(19) United States
(12) Patent Application Publication
(10) Pub. No.: US 2026/0279257 A1
(43) Pub. Date: Sep. 17, 2026

(54) DISPLAY DEVICE AND ELECTRONIC DEVICE INCLUDING THE SAME

(71) Applicant: Samsung Display Co., Ltd., Yongin-si (KR)

(72) Inventors: GICHANG LEE, Yongin-si (KR); Dongwan HA, Yongin-si (KR)

(21) Appl. No.: 19/422,044

(22) Filed: Dec. 16, 2025

(30) Foreign Application Priority Data
Mar. 13, 2025 (KR) 10-2025-0032806

(51) Int. Cl. G09G 3/32

(52) U.S. Cl. CPC G09G 3/32; G09G 2300/043; G09G 2300/0465; G09G 2300/0819; G09G 2310/08

(57) ABSTRACT

on the semiconductor substrate, each of the pixels including: a light emitting element; a driving transistor connected between a first driving voltage line configured to receive a first driving voltage and a first node; a write transistor connected to a data line and configured to receive a write scan signal; and a switching transistor connected between the first node and the light emitting element and configured to receive a switching scan signal, wherein the switching scan signal comprises a first period having a first voltage level, a second period having a second voltage level, and a third period having a third voltage level.

### CROSS-REFERENCE TO RELATED APPLICATION

The present application claims priority to and the benefit of Korean Patent Application No. 10-2025-0032806, filed on Mar. 13, 2025, in the Korean Intellectual Property Office, the entire disclosure of which is incorporated herein by reference.

### BACKGROUND

### 1. Field

Aspects of some embodiments of the present disclosure relate to a display device and an electronic device including the same.

### 2. Description of the Related Art

Electronic devices, such as smartphones, notebook computers, navigation devices, and smart televisions, include a display device to provide images to a user. An augmented reality device, a virtual reality device, or a video projection device may include a microdisplay. The microdisplay may include a silicon wafer and a light emitting element located on the silicon wafer to display a high-brightness image while being driven at relatively low power.

The above information disclosed in this Background section is only for enhancement of understanding of the background and therefore the information discussed in this Background section does not necessarily constitute prior art.

### SUMMARY

Aspects of some embodiments of the present disclosure relate to a display device and an electronic device including the same. For example, aspects of some embodiments of the present disclosure relate to a display device with relatively improved pixel density and an electronic device including the display device.

Aspects of some embodiments of the present disclosure include a display device including a semiconductor substrate and an electronic device including the display device.

Aspects of some embodiments of the present disclosure include a display device including a semiconductor substrate and a plurality of pixels on the semiconductor substrate. According to some embodiments, each of the pixels includes a light emitting element, a driving transistor connected between a first driving voltage line receiving a first driving voltage and a first node, a write transistor connected to a data line and receiving a write scan signal, and a switching transistor connected between the first node and the light emitting element and receiving a switching scan signal. According to some embodiments, the switching scan signal includes a first period having a first voltage level, a second period having a second voltage level, and a third period having a third voltage level.

According to some embodiments, the switching transistor is turned on in response to the switching scan signal having the first voltage level during the first period and the third voltage level during the third period and is turned off in response to the switching scan signal having the second voltage level during the second period.

According to some embodiments, the first voltage level is lower than a value obtained by subtracting a threshold voltage of the driving transistor and a threshold voltage of the switching transistor from the first driving voltage.

According to some embodiments, the third voltage level has a voltage level between the first voltage level and the second voltage level.

According to some embodiments, the driving transistor includes a gate connected to a second node, a source connected to the first driving voltage line, and a drain connected to the first node.

According to some embodiments, the switching transistor includes a gate receiving the switching scan signal, a source connected to the first node, and a drain connected to the light emitting element.

According to some embodiments, the write transistor includes a gate receiving the write scan signal, a source connected to the data line, and a drain connected to a third node.

According to some embodiments, each of the pixels further includes a compensation transistor. According to some embodiments, the compensation transistor includes a gate receiving a compensation scan signal, a source connected to the first node, and a drain connected to a second node.

According to some embodiments, each of the pixels further includes an initialization transistor. According to some embodiments, the initialization transistor includes a gate receiving an initialization scan signal, a source connected to an initialization voltage line receiving an initialization voltage, and a drain connected to the light emitting element.

According to some embodiments, each of the pixels further includes a reference transistor. According to some embodiments, the reference transistor includes a gate receiving a reference scan signal, a source connected to a reference voltage line receiving a reference voltage, and a drain connected to the third node.

According to some embodiments, each of the pixels further includes a capacitor connected between the second node and the third node.

According to some embodiments, the display device operates in the unit of frame, and the frame includes the first period, the second period, and the third period.

According to some embodiments, the reference scan signal, the compensation scan signal, and the initialization scan signal include an active period in the first period, and the write scan signal includes a non-active period in the first period.

According to some embodiments, the compensation scan signal, the write scan signal, and the initialization scan signal include the active period in the second period, and the reference scan signal includes the non-active period in the second period.

According to some embodiments, the display device further includes a demultiplexer. According to some embodiments, the demultiplexer transmits a first sub-data signal in response to a first control signal, transmits a second sub-data signal in response to a second control signal, and transmits a third sub-data signal in response to a third control signal.

According to some embodiments, the first control signal and the second control signal are activated at a different time from the second period, and the third control signal is activated during the second period.

According to some embodiments, the first control signal, the second control signal, and the third control signal are sequentially activated during a horizontal scan period between the first period and the third period, and a duration of the second period is one-third of the horizontal scan period.

Aspects of some embodiments of the present disclosure include an electronic device including a display device, a processor controlling an operation of the display device, and a power module supplying a power. According to some embodiments, the display device includes a semiconductor substrate and a plurality of pixels on the semiconductor substrate. According to some embodiments, each of the pixels includes a light emitting element, a driving transistor connected between a first driving voltage line receiving a first driving voltage and a first node, a write transistor connected to a data line and receiving a write scan signal, and a switching transistor connected between the first node and the light emitting element and receiving a switching scan signal. According to some embodiments, the switching scan signal includes a first period having a first voltage level, a second period having a second voltage level, and a third period having a third voltage level.

According to some embodiments, the switching transistor is turned on in response to the switching scan signal having the first voltage level during the first period and the third voltage level during the third period and is turned off in response to the switching scan signal having the second voltage level during the second period.

According to some embodiments, the third voltage level has a voltage level between the first voltage level and the second voltage level.

According to some embodiments, the first voltage level is lower than a value obtained by subtracting a threshold voltage of the driving transistor and a threshold voltage of the switching transistor from the first driving voltage.

According to some embodiments of the present disclosure, a switching transistor may be driven by the switching scan signal that has three voltage levels. Without adding any extra transistors, the switching transistor may perform operations of initializing the gate of the driving transistor to the initialization voltage and relatively reduce grayscale variation caused by a deterioration of an anode. Accordingly, the number of the transistors may be relatively reduced, and integration density may be relatively improved.

### BRIEF DESCRIPTION OF THE DRAWINGS

FIG. 1 is a perspective view illustrating a display device according to some embodiments of the present disclosure;

FIG. 2 is a cross-sectional view illustrating a display device according to some embodiments of the present disclosure;

FIG. 3A is a plan view illustrating a unit area according to some embodiments of the present disclosure;

FIG. 3B is a cross-sectional view illustrating one light emitting area among a first light emitting area, a second light emitting area, and a third light emitting area of FIG. 3A;

FIG. 4 is a block diagram illustrating a display device according to some embodiments of the present disclosure;

FIG. 5 is an equivalent circuit diagram illustrating a pixel according to some embodiments of the present disclosure;

FIG. 6 is a timing diagram illustrating an operation of a display device according to some embodiments of the present disclosure;

FIG. 7A is a view illustrating an operation of a pixel for a first period according to some embodiments of the present disclosure;

FIG. 7B is a view illustrating an operation of a pixel for a second period according to some embodiments of the present disclosure;

FIG. 7C is a view illustrating an operation of a pixel for a third period according to some embodiments of the present disclosure;

FIG. 8 is a block diagram illustrating a display device including a demultiplexer according to some embodiments of the present disclosure;

FIG. 9 is a timing diagram illustrating an operation of a display device of FIG. 8;

FIG. 10 is a block diagram illustrating an electronic device according to some embodiments of the present disclosure; and

FIG. 11 is a schematic view illustrating various electronic devices according to some embodiments of the present disclosure.

### DETAILED DESCRIPTION

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure. As an example, without departing from the scope of the present disclosure, a first component, a first part, a first region, a first layer, and a first portion are referred to as a second component, a second part, a second region, a second layer, and a second portion, respectively, and vice versa. As used herein, the singular forms, “a”, “an” and “the” are intended to include the plural forms as well, unless the context clearly indicates otherwise.

Spatially relative terms, such as “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, aspects of some embodiments of the present disclosure will be described in more detail with reference to accompanying drawings.

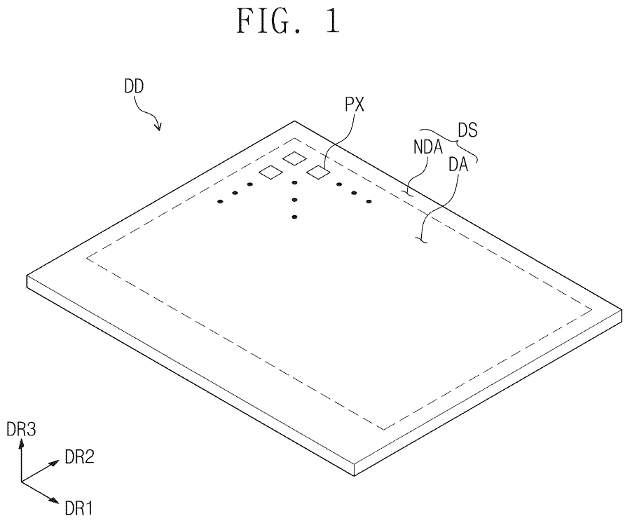

FIG. 1 is a perspective view illustrating a display device according to some embodiments of the present disclosure.

Referring to FIG. 1, the display device DD may include a display surface DS parallel (or substantially parallel) to a plane defined by a first direction DR1 and a second direction DR2. Images may be displayed through the display surface DS. A normal line direction of the display surface DS may be defined as a third direction DR3. In the following descriptions, the expressions “when viewed in a plane” or “in a plan view) may refer to a state of being viewed in the third direction DR3.

According to some embodiments, the display device DD may be a device activated in response to an electrical signal. The display device DD may be employed in a television, a monitor, an outdoor billboard, a tablet computer, a car navigation unit, a personal computer, a notebook computer, a personal digital assistant, a game console, a smartphone, a camera, or a wearable device. For example, the wearable device may include a virtual reality device, an augmented reality device, or a smartwatch. The virtual reality and augmented reality devices may be in the form of glasses that may be worn by a user. These devices are merely examples, and the display device DD may display images through a display area DA according to the present disclosure. A non-display area NDA may surround (e.g., in a periphery or outside a footprint of) the display area DA. Unlike the display device DD illustrated in FIG. 1, the non-display area NDA may be located adjacent to (e.g., outside a footprint of) only one side of the display area DA or may be omitted entirely.

A plurality of pixels PX may be arranged in the display area DA. The pixels PX may be arranged in a matrix form. Each of the pixels PX may include a pixel circuit and a light emitting element. All the pixels PX may emit light of the same color. According to some embodiments of the present disclosure, the pixels PX may include a plurality of groups emitting lights of different colors.

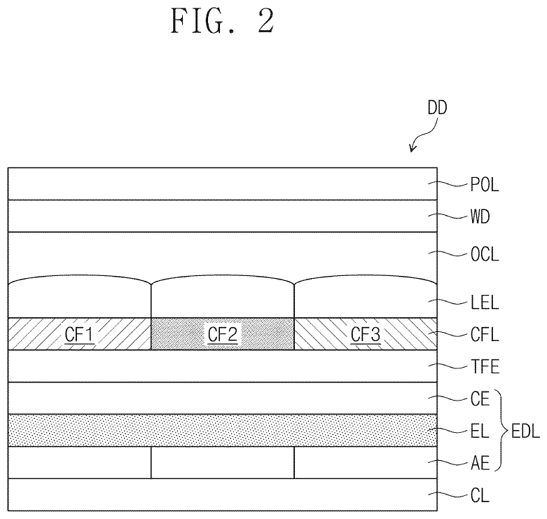

FIG. 2 is a cross-sectional view illustrating the display device according to some embodiments of the present disclosure.

Referring to FIG. 2, the display device DD may include a circuit layer CL, a light emitting element layer EDL, a thin film encapsulation layer TFE, a color filter layer CFL, a lens layer LEL, an overcoating layer OCL, a window WM, and a polarizing layer POL.

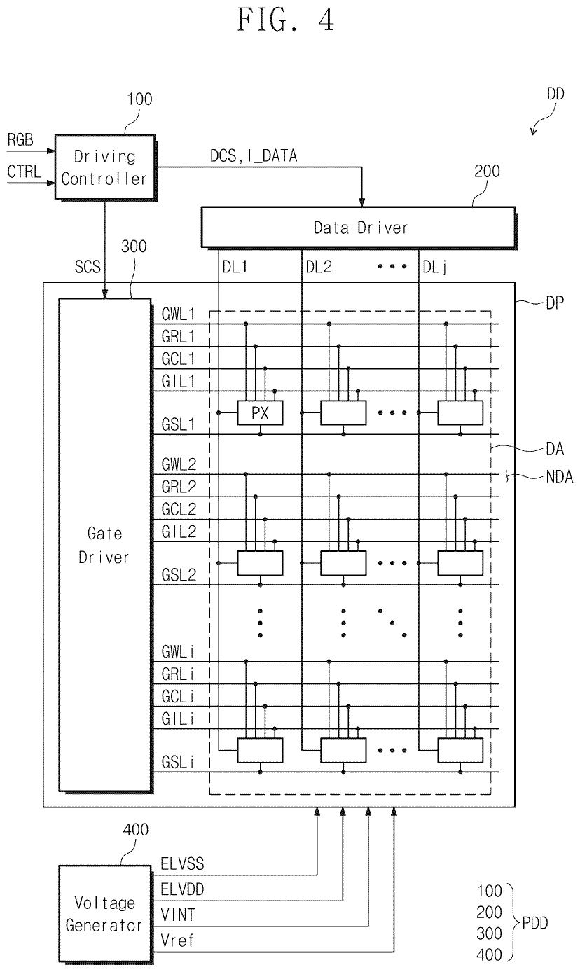

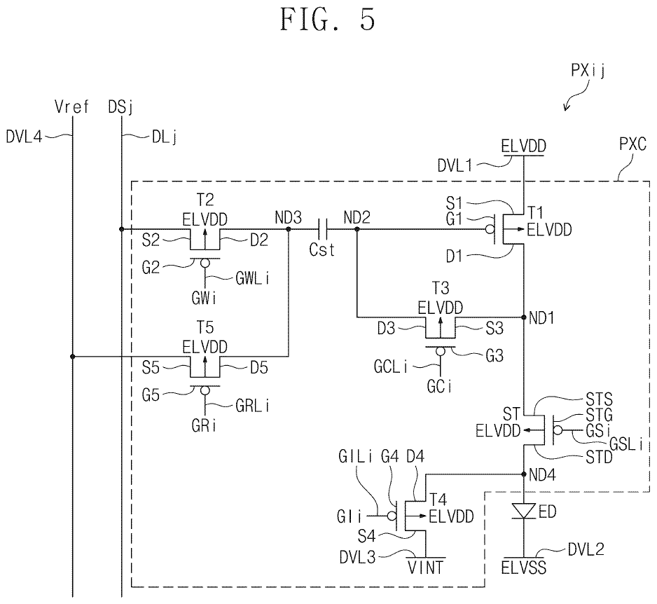

Transistors that form a data driver 200 (refer to FIG. 4), a gate driver 300 (refer to FIG. 4), and a pixel circuit PXC (refer to FIG. 5) may be formed in the circuit layer CL. The circuit layer CL may include at least one insulating layer, a semiconductor pattern, a conductive pattern, and a signal line. An insulating layer, a semiconductor layer, and a conductive layer may be formed by a coating or depositing process. Then, the insulating layer, the semiconductor layer, and the conductive layer may be selectively patterned through several photolithography processes. Then, the semiconductor pattern, the conductive pattern, and the signal line, which are included in the circuit layer CL, may be formed.

The light emitting element layer EDL may be located on the circuit layer CL. The light emitting element layer EDL may include a first electrode AE, a light emitting layer EL, and a second electrode CE. According to some embodiments, the first electrode AE may be an anode, and the second electrode CE may be a cathode.

The first electrode AE may include a transparent conductive oxide pattern. The first electrode AE may be individually formed for each pixel. The transparent conductive oxide pattern may include indium tin oxide (ITO), indium zinc oxide (IZO), indium gallium zinc oxide (IGZO), zinc oxide (ZₙOₓ), indium oxide (In₂O₃), or aluminum-doped zinc oxide (AZO), which facilitate hole injection. The first electrode AE may have a single-layer or multi-layer structure.

The light emitting layer EL may be located on the first electrode AE. The light emitting layer EL may have an integral shape and may be commonly located in the pixels. When the light emitting layer EL has the integral shape, the light emitting layer EL may emit a blue light or a while light. However, embodiments according to the present disclosure are not limited thereto or thereby, and the light emitting layer EL may be individually formed for each pixel. When the light emitting layer EL is individually formed for each pixel, each of the light emitting layers EL may emit at least one light among a first color light, a second color light, and a third color light. The light emitting layer EL may include an organic light emitting material, a quantum dot, a quantum rod, a micro-LED, or a nano-LED.

The second electrode CE may be located on the light emitting layer EL. The second electrode CE may have an integral shape and may be commonly arranged in the pixels. A common voltage may be applied to the second electrode CE, and the second electrode CE may be referred to as a common electrode.

The thin film encapsulation layer TFE may be located on the light emitting element layer EDL. The thin film encapsulation layer TFE may protect the light emitting element layer EDL from moisture, oxygen, and a foreign substance, e.g., dust particles. The encapsulation layer TFE may include at least one inorganic layer (hereinafter, referred to as an encapsulation inorganic layer). In addition, the encapsulation layer TFE may further include at least one organic layer (hereinafter, referred to as an encapsulation organic layer). The thin film encapsulation layer TFE may include the encapsulation inorganic layer, the encapsulation organic layer, and the encapsulation inorganic layer, which are sequentially stacked, however, layers for the thin film encapsulation layer TFE should not be limited thereto or thereby.

The color filter layer CFL may be located on the thin film encapsulation layer TFE. The color filter layer CFL may include a plurality of color filters CF1, CF2, and CF3. The color filters CF1, CF2, and CF3 may include a first color filter CF1, a second color filter CF2, and a third color filter CF3. The first color filter CF1 may convert the color light, e.g., the blue light, emitted from the light emitting layer EL into the first color light to output the first color light, and the second color filter CF2 may convert the color light emitted from the light emitting layer EL into the second color light to output the second color light. The third color filter CF3 may transmit the color light emitted from the light emitting layer EL without converting to output the third color light. According to some embodiments, the color filter layer CFL may further include a light blocking pattern.

The lens layer LEL may be located on the color filter layer CFL. The lens layer LEL may include a plurality of lens patterns. The lens patterns may be arranged to respectively correspond to the first, second, and third color filters CF1, CF2, and CF3 and may be spaced apart from each other.

The overcoating layer OCL may be located on the lens layer LEL. The overcoating layer OCL may be optically transparent. The overcoating layer may serve as a planarization layer with a flat upper surface.

The window WM may be located on the overcoating layer OCL. The window WM may provide an exterior of the display device DD.

The polarizing layer POL may be located on the window WM. The polarizing layer POL may block an external light incident to the display device DD from the outside. The polarizing layer POL may block a portion of the external light. In addition, the polarizing layer POL may reduce a reflected light generated by the external light in a display panel DP (refer to FIG. 4). That is, the polarizing layer POL may be an anti-reflective layer. As an example, the polarizing layer POL may block the reflected light generated when the light incident from the outside of the display device DD re-exits again after entering the display panel DP (refer to FIG. 4).

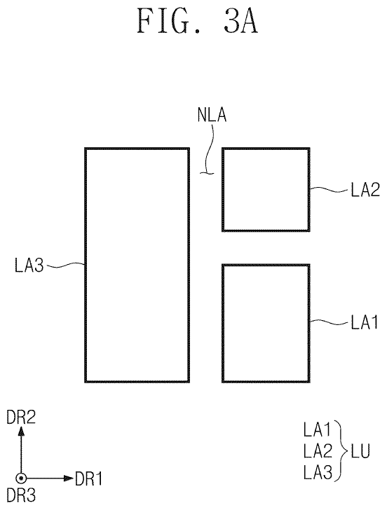

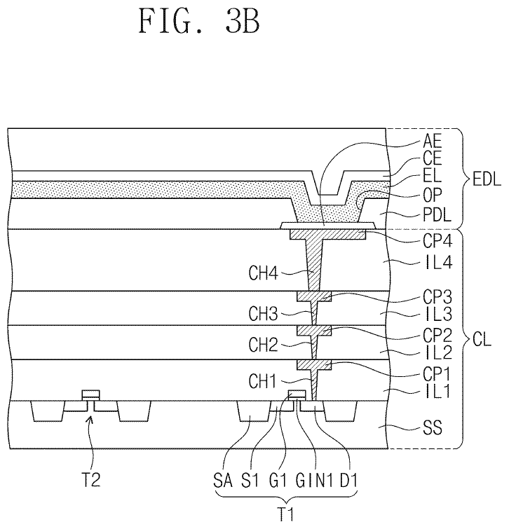

FIG. 3A is a plan view illustrating a unit area according to some embodiments of the present disclosure.

FIG. 3A illustrates the unit area LU that is repeatedly arranged in the display area DA of FIG. 1. The unit area LU may include a first light emitting area LA1, a second light emitting area LA2, and a third light emitting area LA3. As an example of the present disclosure, a first light emitting element of a first pixel, a second light emitting element of a second pixel, and a third light emitting element of a third pixel may be located in the first light emitting area LA1, the second light emitting area LA2, and the third light emitting area LA3, respectively.

The first color light, the second color light, and the third color light may be emitted through the first light emitting area LA1, the second light emitting area LA2, and the third light emitting area LA3. The first light emitting element, the second light emitting element, and the third light emitting element may generate the same color light, for example, the blue light, using the light emitting layer EL (refer to FIG. 2) with an integral shape. The color filters located respectively in the first, second, and third light emitting areas may convert the color light generated from the light emitting layer EL (refer to FIG. 2) with an integral shape into the first color light, the second color light, and the third color light or may transmit the color light generated from the light emitting layer EL (refer to FIG. 2). According to some embodiments of the present disclosure, light emitting elements that generate different color lights may also be located in the first, second, and third light emitting areas.

A red light may be emitted through the first light emitting area LA1, a green light may be emitted through the second light emitting area LA2, and a blue light may be emitted through the third light emitting area LA3. An arrangement of the first, second, and third light emitting areas, an area ratio between the first, second, and third light emitting areas, and the shape of the first, second, and third light emitting areas shown in FIG. 3A are merely illustrative examples and should not be limited thereto or thereby.

FIG. 3B is a cross-sectional view illustrating one light emitting area among the first light emitting area, the second light emitting area, and the third light emitting area of FIG. 3A.

FIG. 3B illustrates the circuit layer CL and the light emitting element layer EDL of the cross-section of the display device DD shown in FIG. 2. Because components of the light emitting element layer EDL shown in FIG. 3B are similar to components of the light emitting element layer EDL shown in FIG. 2, the same components are assigned with the same reference numerals, and some details thereof may be omitted.

The circuit layer CL may include a semiconductor substrate SS, at least one insulating layer IL1 to IL4, and at least one conductive pattern CP1 to CPL4. Contact holes CH1, CH2, CH3, and CH4 may be defined through the insulating layers IL1 to IL4, respectively. According to some embodiments, the circuit layer CL including four insulating layers IL1 to IL4 and four conductive patterns CP1 to CP4 is illustrated as a representative example.

The semiconductor substrate SS may be a silicon substrate, a germanium substrate, or a silicon-germanium substrate. A plurality of pixels PX (refer to FIG. 4) may be formed on the semiconductor substrate SS. The semiconductor substrate SS may include a source S1 and a drain D1. Each of the source S1 and the drain D1 may be a region doped with impurities. A pair of the source S1 and the drain D1 may define a transistor, for example, a first transistor T1, together with a gate G1 to be described later. Shallow trench isolation (STI) areas SA may further be defined in the semiconductor substrate SS. The STI areas SA may isolate the transistors to prevent or reduce a leakage current occurring. The arrangement of the STI areas SA may vary depending on the design of the pixel circuit.

A gate insulating layer GIN1 and the gate G1 may be arranged on the semiconductor substrate SS. The gate G1 may include a metal material. The gate G1 may be arranged to correspond to the pair of the source S1 and the drain D1. The gate insulating layer GIN1 may include insulating patterns arranged to correspond to the gate G1.

A first insulating layer IL1 may be located on the semiconductor substrate SS. The first insulating layer IL1 may commonly overlap the pixels and may cover gates of the transistors T1 and T2. The first insulating layer IL1 may be an inorganic layer and/or an organic layer and may have a single-layer or multi-layer structure. The first insulating layer IL1 may include at least one of aluminum oxide, titanium oxide, silicon oxide, silicon nitride, silicon oxynitride, zirconium oxide, or hafnium oxide. According to some embodiments, the first insulating layer IL1 may have the single-layer of a silicon oxide layer. Not only the first insulating layer IL1, but also second to fourth insulating layers IL2 to IL4, which will be described in more detail later, may be an inorganic layer and/or an organic layer and may have a single-layer or multi-layer structure. The inorganic layer may include at least one of the above-described materials, but it should not be limited thereto or thereby.

A first conductive pattern CP1 may be located on the first insulating layer IL1. The first conductive pattern CP1 may be connected to the source and/or drain of the transistors T1 and T2 through a first contact hole CH1. According to some embodiments, the first conductive pattern CP1 is illustrated as being connected to the drain D1 of the first transistor T1. In addition to the first conductive pattern CP1, second, third, and fourth conductive patterns CP2, CP3, and CP4, which will be described later, may be defined as contact electrodes. Upper surfaces of the conductive patterns CP1 to CP4 may define the same plane (or a continuous surface from the upper surfaces of the insulating layers IL1 to IL4) as upper surfaces of the insulating layers IL1 to IL4. The conductive patterns CP1 to CP4 may be formed through a chemical mechanical polishing process, such as a damascene process. The conductive patterns CP1 to CP4 should not be particularly limited as long as the conductive patterns CP1 to CP4 include a material with high electrical conductivity and high reflectivity. For example, the conductive patterns CP1 to CP4 may include one of copper (Cu), aluminum (AI), tungsten (W), molybdenum (Mo), chromium (Cr), gold (Au), titanium (Ti), nickel (Ni), neodymium (Nd), or an alloy containing at least one thereof.

The second insulating layer IL2 may be located on the first insulating layer IL1 and may commonly overlap the pixels. The second insulating layer IL2 may be an inorganic layer and/or an organic layer and may have a single-layer or multi-layer structure. According to some embodiments, the second insulating layer IL2 may have a single-layer structure of a silicon oxide layer. The second conductive pattern CP2 may be located on the second insulating layer IL2. The second conductive pattern CP2 may be connected to the first conductive pattern CP1 through a second contact hole CH2.

A third insulating layer IL3 may be located on the second insulating layer IL2 and may commonly overlap the pixels. The third insulating layer IL3 may be an inorganic layer and/or an organic layer and may have a single-layer or multi-layer structure. According to some embodiments, the third insulating layer IL3 may have a single-layer structure of a silicon oxide layer. A third conductive pattern CP3 may be located on the third insulating layer IL3. The third conductive pattern CP3 may be connected to the second conductive pattern CP2 through a third contact hole CH3.

The fourth insulating layer IL4 may be located on the third insulating layer IL3 and may commonly overlap the pixels. The fourth insulating layer IL4 may be an inorganic layer and/or an organic layer and may have a single-layer or multi-layer structure. According to some embodiments, the fourth insulating layer IL4 may have a single-layer structure of a silicon oxide layer. The fourth conductive pattern CP4 may be located on the fourth insulating layer IL4. The fourth conductive pattern CP4 may be connected to the third conductive pattern CP3 through a fourth contact hole CH4.

The fourth conductive pattern CP4 may electrically connect the third conductive pattern CP3 located under the fourth conductive pattern CP4 and the first electrode AE located on the fourth conductive pattern CP4. In addition, the fourth conductive pattern CP4 may function as a reflective layer of the light emitting element. The light emitting element may utilize a resonance phenomenon to enhance the light-exit efficiency of the light generated in a light emitting unit. Two reflective layers may be located at opposite sides of the light emitting unit to induce the resonance phenomenon. A semi-transparent reflective layer may be located on a side from which the light exits, and an opaque reflective layer with high reflectance may be located on the opposite side. The fourth conductive pattern CP4 may serve as the opaque reflective layer.

The light emitting element layer EDL may be located on the fourth insulating layer IL4. The light emitting element layer EDL shown in FIG. 3B may further include a pixel definition layer PDL compared to the light emitting element layer EDL shown in FIG. 2. The pixel definition layer PDL may be an organic layer. According to some embodiments, the pixel definition layer PDL having a single-layer structure is illustrated as a representative example, however, embodiments according to the present disclosure are not limited thereto or thereby. An opening OP may be defined through the pixel definition layer PDL to expose a portion of the first electrode AE.

The opening OP may define a corresponding light emitting area among the light emitting areas LA1, LA2, and LA3 shown in FIG. 3A. The opening OP may be located inside the fourth conductive pattern CP4 when viewed in the plane (e.g., in a plan view) to align the light emitting area of the light emitting layer EL with a reflective region of the fourth conductive pattern CP4. The light generated within the light emitting areas LA1, LA2, and LA3 may be sufficiently reflected by the fourth conductive pattern CP4, which has a larger area. The opening OP may have a width smaller than a width of the fourth conductive pattern CP4.

FIG. 4 is a block diagram illustrating the display device according to some embodiments of the present disclosure.

Referring to FIG. 4, the display device DD may include the display panel DP and a panel driver PDD. As an example, the panel driver PDD may include a driving controller 100, a data driver 200, a gate driver 300, and a voltage generator 400, but embodiments according to the present disclosure are not limited thereto, and the panel driver PDD may include additional components, or fewer components, without departing from the spirit and scope of embodiments according to the present disclosure.

The display panel DP may include the display area DA and the non-display area NDA surrounding (e.g., in a periphery, or outside a footprint of) at least a portion of the display area DA. The display panel DP may include the pixels PX arranged in the display area DA. The display panel DP may include write scan lines GWL1 to GWLi, reference scan lines GRL1 to GRLi, compensation scan lines GCL1 to GCLi, initialization scan lines GIL1 to GILi, and switching scan lines GSL1 to GSLi. According to some embodiments, “i” may be an integer (or a natural number) greater than or equal to 1.

The driving controller 100 may receive input image signals RGB and a control signal CTRL. The driving controller 100 may convert a data format of the input image signals RGB to a data format appropriate to an interface between the data driver 200 and the driving controller 100 to generate image data I_DATA. The driving controller 100 may output a first driving control signal SCS and a second driving control signal DCS.

The data driver 200 may receive the second driving control signal DCS and the image data I_DATA from the driving controller 100. The data driver 200 may convert the image data I_DATA into data signals and may output the data signals to a plurality of data lines DL1 to DLj. The data signals may be analog voltages corresponding to a grayscale level of the image signal I_DATA. According to some embodiments, “j” may be an integer (or a natural number) greater than or equal to 1. The gate driver 300 may receive the first driving control signal SCS from the driving controller 100. The gate driver 300 may be connected to the write scan lines GWL1 to GWLi, the reference scan lines GRL1 to GRLi, the compensation scan lines GCL1 to GCLi, the initialization scan lines GIL1 to GILi, and the switching scan lines GSL1 to GSLi. The gate driver 300 may output a write scan signal, a reference scan signal, a compensation scan signal, initialization scan signals, and switching scan signals to the write scan lines GWL1 to GWLi, the reference scan lines GRL1 to GRLi, the compensation scan lines GCL1 to GCLi, the initialization scan lines GIL1 to GILi, and the switching scan lines GSL1 to GSLi, respectively, in response to the first driving control signal SCS. The gate driver 300 may be located in the non-display area NDA of the display panel DP.

The voltage generator 400 (or a power supply) may generate voltages required for the operation of the display panel DP. According to some embodiments, the voltage generator 400 may generate a first driving voltage ELVDD, a second driving voltage ELVSS, an initialization voltage VINT, and a reference voltage Vref. Each of the pixels PX may include a light emitting element ED (refer to FIG. 5) and a pixel circuit PXC (refer to FIG. 5) controlling an emission of the light emitting element ED. The pixel circuit PXC may include at least one transistor and at least one capacitor. The gate driver 300 may include transistors formed through the same process as the pixel circuit PXC.

Each of the pixels PX may be electrically connected to the write scan lines GWL1 to GWLi, the reference scan lines GRL1 to GRLi, the compensation scan lines GCL1 to GCLi, the initialization scan lines GIL1 to GILi, the switching scan lines GSL1 to GSLi, and the data lines DL1 to DLj. As an example, the pixels arranged in an i-th row may be connected to i-th write, reference, compensation, initialization, and switching scan lines GWLi, GRLi, GCLi, GILi, and GSLi. The pixels arranged in a j-th column may be connected to a j-th data line DLj. However, the present disclosure should not be limited thereto or thereby, and each of the pixels PX may be connected to more than five scan lines.

Each of the pixels PX may be connected to a first driving voltage line DVL1 (refer to FIG. 5), a second driving voltage line DVL2 (refer to FIG. 5), a third driving voltage line DVL3 (refer to FIG. 5), and a fourth driving voltage line DVL4 (refer to FIG. 5). The first driving voltage line DVL1 may receive the first driving voltage ELVDD from the voltage generator 400, and the second driving voltage line DVL2 may receive the second driving voltage ELVSS from the voltage generator 400. The third driving voltage line DVL3 may receive the initialization voltage VINT from the voltage generator 400, and the fourth driving voltage line DVL4 may receive the reference voltage Vref from the voltage generator 400.

FIG. 5 is an equivalent circuit diagram illustrating a pixel according to some embodiments of the present disclosure. Although FIG. 5 illustrates various components in a pixel according to some embodiments, embodiments according to the present disclosure are not limited thereto, and according to various embodiments, the pixel may include additional components, or fewer components, without departing from the spirit and scope of embodiments according to the present disclosure.

FIG. 5 illustrates an equivalent circuit diagram of one pixel PXij among the pixels PX (refer to FIG. 4) as a representative example. Because the pixels PX illustrated in FIG. 4 have the same circuit configuration, a detailed description of the other pixels PX will be omitted, and the circuit configuration of the pixel PXij will be described in detail.

Referring to FIG. 5, the pixel PXij may include the light emitting element ED and the pixel circuit PXC. The pixel PXij may be connected to an i-th write scan line GWLi (hereinafter, referred to as a write scan line) among the write scan lines GWL1 to GWLi (refer to FIG. 4), an i-th reference scan line GRLi (hereinafter, referred to as a reference scan line) among the reference scan lines GRL1 to GRLi (refer to FIG. 4), an i-th compensation scan line GCLi (hereinafter, referred to as a compensation scan line) among the compensation scan lines GCL1 to GCLi (refer to FIG. 4), an i-th initialization scan line GILi (hereinafter, referred to as an initialization scan line) among the initialization scan lines GIL1 to GILi, and an i-th switching scan line GSLi (hereinafter, referred to as a switching scan line) among the switching scan lines GSL1 to GSLi (refer to FIG. 4). In addition, the pixel PXij may be connected to a j-th data line DLj (hereinafter, referred to as a data line) among the data lines DL1 to DLj.

The write scan line GWLi, the reference scan line GRLi, the compensation scan line GCLi, the initialization scan line GILi, and the switching scan line GSLi may transmit an i-th write scan signal GWi (hereinafter, referred to as a write scan signal), an i-th reference scan signal GRi (hereinafter, referred to as a reference scan signal), an i-th compensation scan signal GCi (hereinafter, referred to as a compensation scan signal), an i-th initialization scan signal GIi (hereinafter, referred to as an initialization scan signal), and an i-th switching scan signal GSi (hereinafter, referred to as a switching scan signal) to the pixel PXij, respectively. The data line DLj may transmit a j-th data signal DSj (hereinafter, referred to as a data signal) to the pixel PXij. The data signal DSj may have a voltage level corresponding to a grayscale of a corresponding image signal among the image signals RGB input to the display device DD (refer to FIG. 4). The first, second, third, and fourth driving voltage lines DVL1, DVL2, DVL3, and DVL4 may transmit the first driving voltage ELVDD, the second driving voltage ELVSS, the initialization voltage VINT, and the reference voltage Vref to the pixel PXij, respectively.

The pixel circuit PXC may include a plurality of transistors T1, T2, T3, T4, T5, and ST and a capacitor Cst. The circuit configuration of the pixel circuit PXC should not be limited to the embodiments illustrated in FIG. 5. The pixel circuit PXC illustrated in FIG. 5 is merely an example, and the circuit configuration of the pixel circuit PXC may be changed. As an example, the pixel circuit PXC may further include at least one transistor and at least one capacitor.

According to some embodiments, each of the transistors T1, T2, T3, T4, T5, and ST is described as a P-type transistor, however, the present disclosure should not be limited thereto or thereby. According to some embodiments, at least one of the transistors T1, T2, T3, T4, T5, or ST may be an N-type transistor.

In addition, each of the transistors T1, T2, T3, T4, T5, and ST may be a transistor including a low-temperature polycrystalline silicon (LTPS) semiconductor layer, however, the present disclosure should not be limited thereto or thereby. According to some embodiments, at least one of the transistors T1, T2, T3, T4, T5, or ST may be a transistor including an oxide semiconductor layer.

The first transistor T1 may be electrically connected between the first driving voltage line DVL1 and a first node ND1. The st T1 may include a source S1 electrically connected to the first driving voltage line DVL1, a drain D1 connected to the first node ND1, and a gate connected to a second node ND2. The first transistor T1 may control an amount of current flowing through the light emitting element ED in response to a voltage at the second node ND2. The first transistor T1 may be referred to as a driving transistor.

The second transistor T2 may be electrically connected between the data line DLj and a third node ND3. The second transistor T2 may include a source S2 connected to the data line DLj, a drain D2 connected to the third node ND3, and a gate G2 connected to the write scan line GWLi. The second transistor T2 may be turned on in response to the write scan signal GWi provided through the write scan line GWLi and may transmit a data signal DSj received from the data line DLj to the third node ND3. The second transistor T2 may be referred to as a write transistor

The third transistor T3 may be electrically connected between the first node ND1 and the second node ND2. The third transistor T3 may include a source S3 connected to the first node ND1, a drain D3 connected to the second node ND2, and a gate G3 connected to the compensation scan line GCLi. The third transistor T3 may be turned on in response to the compensation scan signal GCi provided through the compensation scan line GCLi and may connect the gate G1 and the drain D1 of the first transistor T1 to each other, and thus, the first transistor T1 may be connected in a diode configuration. The third transistor T3 may be referred to as a compensation transistor.

The fourth transistor T4 may be electrically connected between the third driving voltage line DVL3 and a fourth node ND4. The fourth transistor T4 may include a source S4 connected to the third driving voltage line DVL3, a drain D4 connected to the fourth node ND4, and a gate G4 connected to the initialization scan line GILi. The fourth transistor T4 may be turned on in response to the initialization scan signal GIi provided through the initialization scan line GILi and may perform an operation of initializing the fourth node ND4 by transmitting the initialization voltage VINT to the fourth node ND4. The fourth transistor T4 may be referred to as an initialization transistor

The fifth transistor T5 may be connected between the fourth driving voltage line DVL4 and the third node ND3. The fifth transistor T5 may include a source S5 connected to the fourth driving voltage line DVL4, a drain D5 connected to the third node ND3, and a gate G5 connected to the reference scan line GRLi. The fifth transistor T5 may be turned on in response to the reference scan signal GRi provided through the reference scan line GRLi and may transmit the reference voltage Vref to the third node ND3. The fifth transistor T5 may be referred to as a reference transistor.

The switching transistor ST may be connected between the first node ND1 and the fourth node ND4. The switching transistor ST may include a source STS connected to the first node ND1, a drain STD connected to the fourth node ND4, and a gate STG connected to the switching scan line GSLi. The switching transistor ST may be turned on in response to the switching scan signal GSi provided through the switching scan line GSLi. Detailed descriptions of the operation performed when the switching transistor ST is turned on will be provided later.

One end of the capacitor Cst may be connected to the second node ND2, and the other end of the capacitor Cst may be connected to the third node ND3. A voltage corresponding to a difference voltage between the second node ND2 and the third node ND3 may be charged in the capacitor Cst.

The anode of the light emitting element ED may be connected to the fourth node ND4, and the cathode of the light emitting element ED may be connected to the second driving voltage line DVL2 that transmits the second driving voltage ELVSS. The light emitting element ED, the fourth transistor T4, and the switching transistor ST may be electrically connected to each other at the fourth node ND4.

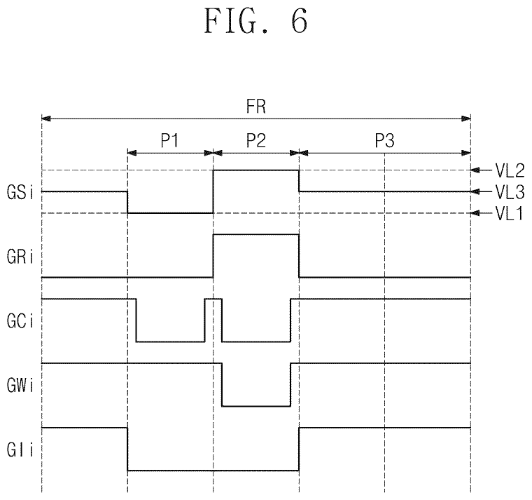

FIG. 6 is a timing diagram illustrating an operation of the display device according to some embodiments of the present disclosure.

Referring to FIG. 6, the display device DD (refer to FIG. 4) may operate in the unit of frame FR. The frame FR may include a first period P1, a second period P2, and a third period P3. The first to third periods P1 to P3 may proceed sequentially. The switching scan signal GSi may have a first voltage level VL1 during the first period P1, a second voltage level VL2 during the second period P2, and a third voltage level VL3 during the third period P3. As an example of the present disclosure, the second voltage level VL2 may be higher than the first voltage level VL1 and the third voltage level VL3, and the third voltage level VL3 may have a voltage level between the first voltage level VL1 and the second voltage level VL2. In the case where the switching transistor ST described with reference to FIG. 5 is the P-type transistor, the switching transistor ST may be turned on in response to the first voltage level VL1 during the first period P1 and the third voltage level VL3 during the third period P3 of the switching scan signal GSi and may be turned off in response to the second voltage level VL2 during the second period P2 of the switching scan signal GSi.

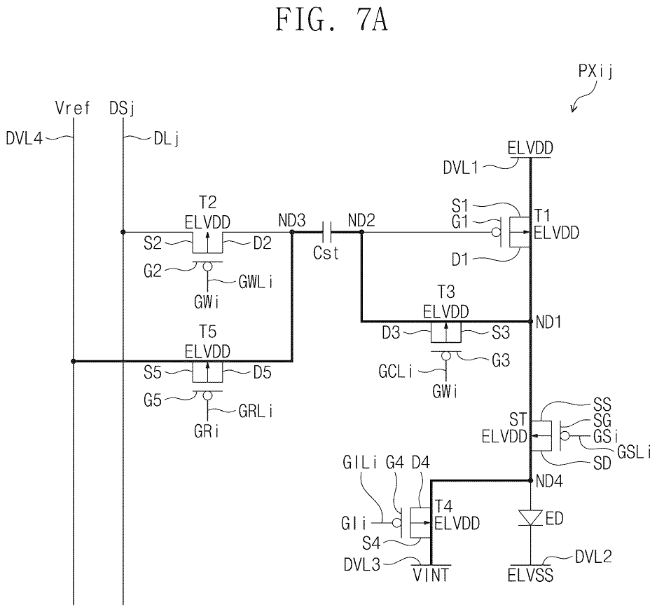

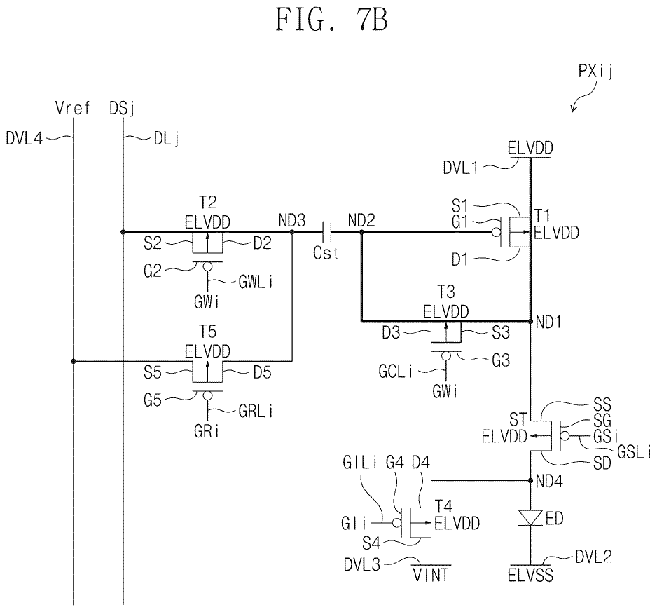

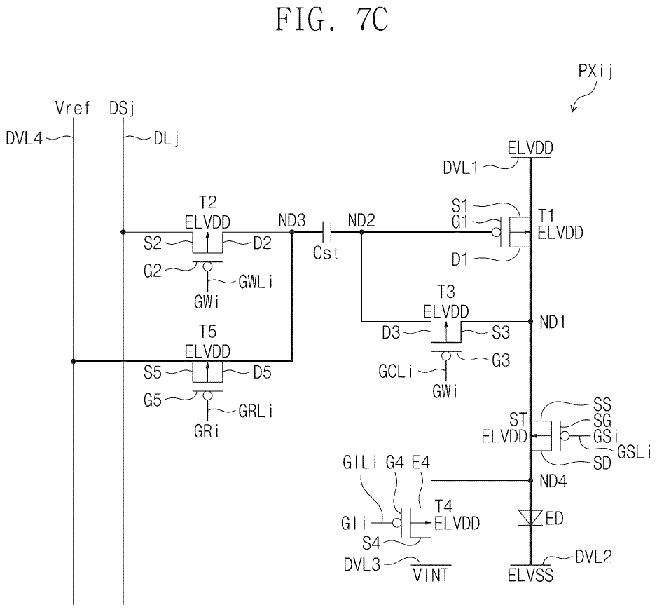

Each of the reference scan signal GRi, the compensation scan signal GCi, the write scan signal GWi, and the initialization scan signal GIi may have an active level (or a low level) during a certain period, i.e., an active period, and a non-active level (or a high level) during the remaining period, i.e., a non-active period. In the case where the first to fifth transistors T1 to T5 described with reference to FIG. 5 are P-type transistors, the active level of each of the reference scan signal GRi, the compensation scan signal GCi, the write scan signal GWi, and the initialization scan signal GIi may be the low level. Alternatively, in the case where the first to fifth transistors T1 to T5 are N-type transistors, the active level of each of the reference scan signal GRi, the compensation scan signal GCi, the write scan signal GWi, and the initialization scan signal GIi may be the high level. Hereinafter, the operation of the pixels during the first to third periods P1 to P3 will be described with reference to FIG. 6 and FIGS. 7A to 7C.

FIG. 7A is a view illustrating an operation of the pixel for the first period according to some embodiments of the present disclosure.

Referring to FIGS. 6 and 7A, the switching scan signal GSi may have the first voltage level VL1 during the first period P1. Additionally, during the first period P1, the reference scan signal GRi, the compensation scan signal GCi, and the initialization scan signal GIi may have the active level while the write scan signal GWi has the non-active level. The first period P1 may begin when the switching scan signal GSi has the first voltage level VL1. As an example of the present disclosure, the first voltage level VL1 of the switching scan signal GSi may be a voltage level that turns on the switching transistor ST to operate in a first saturation region.

During the first period P1, the fifth transistor T5 may be turned on in response to the reference scan signal GRi. Accordingly, the third node ND3 may maintain the reference voltage Vref during the first period P1.

During the first period P1, the switching transistor ST may be turned on in response to the switching scan signal GSi, the third transistor T3 may be turned on in response to the compensation scan signal GCi, and the fourth transistor T4 may be turned on in response to the initialization scan signal GIi. Accordingly, during the first period P1, the first node ND1, the second node ND2, and the fourth node ND4 may be initialized to the initialization voltage VINT. That is, the first period P1 may be defined as a period in which the first node ND1, the second node ND2, and the fourth node ND4 are initialized to the initialization voltage VINT.

According to the present disclosure, during the first period P1, the switching transistor ST may be turned on in response to the switching scan signal GSi having the first voltage level VL1. The first voltage level VL1 may be set to be lower than a value obtained by subtracting an absolute value of a threshold voltage of the first transistor T1 and an absolute value of a threshold voltage of the fourth transistor T4 from the first driving voltage ELVDD, as expressed in Equation 1. According to some embodiments, the first voltage level VL1 may be a voltage capable of turning on the switching transistor ST to initialize the first node ND1 to the initialization voltage VINT and minimizing an undesired leakage current flowing to the fourth node ND4.

$$VL 1 < ELVDD - \vert {V}_{th , T 1} \vert - \vert {V}_{th , T 4} \vert$$

FIG. 7B is a view illustrating an operation of the pixel for the second period according to some embodiments of the present disclosure.

Referring to FIGS. 6 and 7B, when the first period P1 ends, the second period P2 may occur. That is, the second period P2 follows the first period P1. The switching scan signal GSi may have the second voltage level VL2

during the second period P2. In addition, during the second period P2, the compensation scan signal GCi, the write scan signal GWi, and the initialization scan signal GIi may have the active level, and the reference scan signal GRi may have the non-active level. The second period P2 may begin at a time when the switching scan signal GSi has the second voltage level VL2. As an example of the present disclosure, the second voltage level VL2 of the switching scan signal GSi may be a voltage level capable of turning off the switching transistor ST.

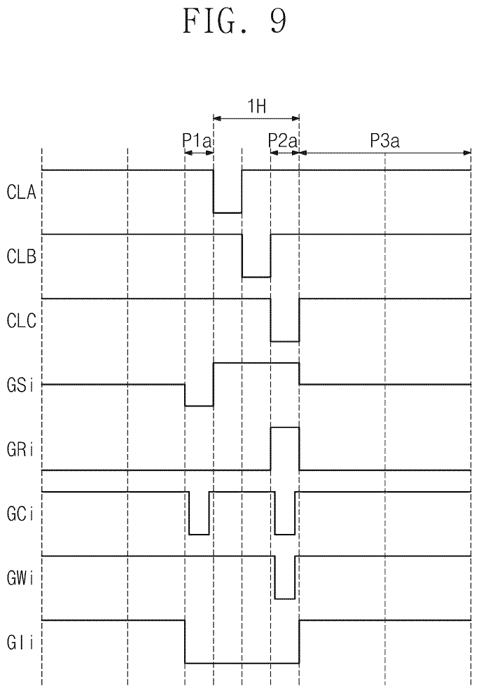

The second transistor T2 may be turned on in response to the write scan signal GWi during the second period P2. Accordingly, the data signal DSj may be applied to the third node ND3 through the second transistor T2 during the second period P2. The second period P2 may correspond to one horizontal scan period 1H (refer to FIG. 9).

The third transistor T3 may be turned on in response to the compensation scan signal GCi during the second period P2. The third transistor T3 may be turned on to diode-connect the first transistor T1. Accordingly, a voltage obtained by removing the threshold voltage of the first transistor T1 from the first driving voltage ELVDD may be applied to the first node ND1. That is, the second period P2 may be defined as a period in which data are written through the second transistor T2 and a period in which the threshold voltage of the first transistor T1 is compensated for through the third transistor T3.

FIG. 7C is a view illustrating an operation of the pixel for the third period according to some embodiments of the present disclosure.

Referring to FIGS. 6 and 7C, when the second period P2 ends, the third period P3 may occur. That is, the third period P3 follows the second period P2.

The switching scan signal GSi may have the third voltage level VL3 during the third period P3. In addition, during the third period P3, the reference scan signal GRi may have the active level, and the compensation scan signal GCi, the write scan signal GWi, and the initialization scan signal GIi may have the non-active level. The third period P3 may begin at a time when the switching scan signal GSi has the third voltage level VL3. As an example of the present disclosure, the third voltage level VL3 of the switching scan signal GSi may be a voltage level capable of turning on the switching transistor ST to operate in a second saturation region.

The fifth transistor T5 may be turned on in response to the reference scan signal GRi during the third period P3. The reference voltage Vref may be applied to the third node ND3 through the turned-on fifth transistor T5 during the third period P3. Accordingly, the voltage of the third node ND3 may vary from the data signal DSj to the reference voltage Vref. The amount of voltage variation at the third node ND3 may be ‘DSj-Vref’ at the start of the third period P3. The amount of voltage variation at the third node ND3 may be transmitted to the second node ND2 through the capacitor Cst, and the voltage of the second node ND2 may also vary. That is, the third period P3 may be defined as an emission period in which a current corresponding to the voltage of the second node ND2 flows to the light emitting element ED through the first transistor T1 and the switching transistor ST and the light emitting element ED emits light at a grayscale level corresponding to the current.

According to the present disclosure, the switching transistor ST may be turned on in response to the switching scan signal GSi having the third voltage level VL3 to operate in the second saturation region, and thus, a constant current may flow through the switching transistor ST. In this case, a variation in the voltage at the fourth node ND4 may not affect the voltage of the first node ND1. As such, even though the anode of the light emitting element ED is deteriorated and the voltage of the fourth node ND4 fluctuates during the third period P3, the variation in voltage at the first node ND1 and the second node ND2 may be minimized by the switching transistor ST driven at the third voltage level VL3 during the third period P3. As an example of the present disclosure, the third voltage level VL3 may be a voltage level capable of turning on the switching transistor ST such that a current corresponding to the voltage of the second node ND2 flows to the light emitting element ED, and the variation in voltage at the first node ND1 may be minimized even though the voltage of the fourth node ND4 fluctuates. Accordingly, since the variation in the grayscale level of the light emitting element ED due to the deterioration of the light emitting element ED is minimized without adding an additional transistor, an integration level of the display device DD may be relatively improved.

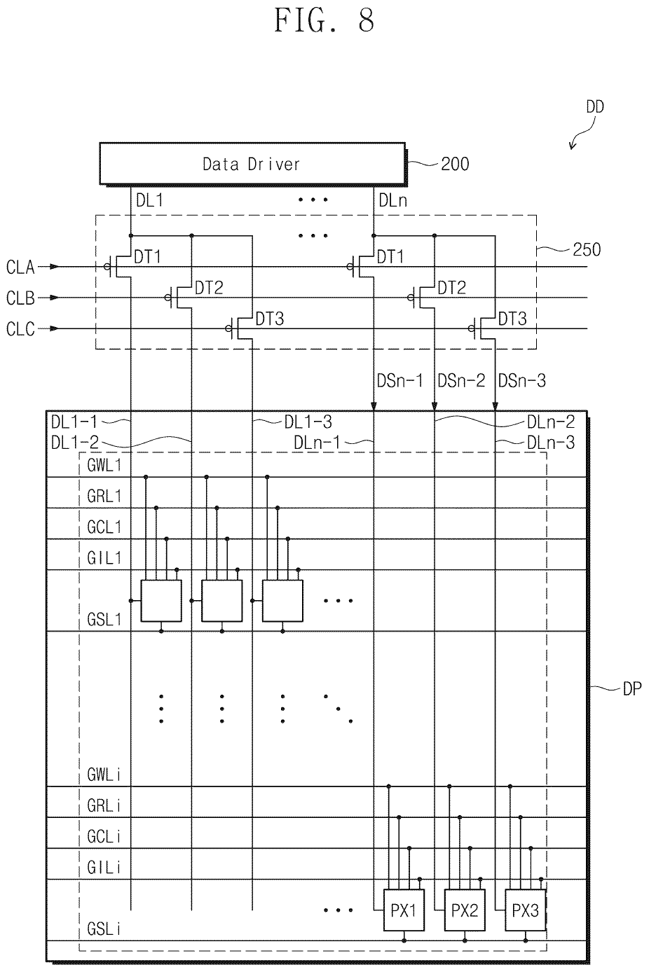

FIG. 8 is a block diagram illustrating a display device including a demultiplexer according to some embodiments of the present disclosure. FIG. 9 is a timing diagram illustrating an operation of the display device of FIG. 8.

Referring to FIG. 8, the display device DD may further include a demultiplexer 250 located between the data driver 200 and the display panel DP.

The data driver 200 may be connected to n data lines DL1 to DLn. In this case, the number of the data lines DL1 to DLn may be one-third of the number of the data lines DL1 to DLj illustrated in FIG. 4. Each of the n data lines DL1 to DLn may be connected to three sub-data lines through the demultiplexer 250. For example, a first data line DL1 may be connected to a first-first sub-data line DL1-1, a first-second sub-data line DL1-2, and a first-third sub-data line DL1-3 through the demultiplexer 250, and an n-th data line DLn may be connected to an (n−1)th sub-data line DLn−1, an (n−2)th sub-data line DLn−2, and an (n−3)th sub-data line DLn−3 through the demultiplexer 250. However, the present disclosure should not be limited thereto or thereby. According to some embodiments, each of the n data lines DL1 to DLn may be connected to two, four, or more sub-data lines. Since the operations of the data lines DL1 to DLn are similar, the following description will focus on the n-th data line DLn, with the explanations for the remaining data lines omitted.

The demultiplexer 250 may include first demux transistors DT1, second demux transistors DT2, and third demux transistors DT3. The first demux transistors DT1 may be turned on in response to a first control signal CLA to connect the n-th data line DLn to the (n−1)th sub-data line DLn−1. The second demux transistors DT2 may be turned on in response to a second control signal CLB to connect the n-th data line DLn to the (n−2)th sub-data line DLn−2. The third demux transistors DT3 may be turned on in response to a third control signal CLC to connect the n-th data line DLn to the (n−3)th sub-data line DLn−3. The (n−1)th to (n−3)th sub-data lines DLn−1 to DLn-3 may be connected to the first, second, and third pixels PX1, PX2, and PX3, respectively, to transmit data signals DSn−1, DSn−2, and DSn−3 to the first, second, and third pixels PX1, PX2, and PX3.

Referring to FIGS. 5, 8, and 9, except that a first period P1a and a second period P2a illustrated in FIG. 9 have a duration shorter than that of the first period P1 and the second period P2 illustrated in FIG. 6, the same operations as those in the first period P1 and the second period P2 shown in FIG. 6 may be performed in the first period P1a and the second period P2a. That is, the third transistor T3, the fourth transistor T4, and the switching transistor ST may be turned on during the first period P1a, and the second node ND2 may be initialized to the initialization voltage VINT. In addition, during the second period P2a, the second transistor T2 may be turned on to apply the data signals DSn−1, DSn−2, and DSn−3 to the third node ND3, and the third transistor T3 may be turned on to perform the operation of compensating for the threshold voltage of the first transistor T1.

The first, second, and third control signals CLA, CLB, and CLC may be sequentially activated during a single horizontal scan period 1H between the first period P1a and the second period P2a. When the first control signal CLA is activated, the first sub-data signal DSn−1 may have a voltage level corresponding to a grayscale of an image to be displayed by the first pixel PX1 and may be applied to the (n−1)th sub-data line DLn−1. When the second control signal CLB is activated, the second sub-data signal DSn−2 may have a voltage level corresponding to a grayscale of an image to be displayed by the second pixel PX2 and may be applied to the (n−2)th sub-data line DLn−2. When the third control signal CLC is activated, the third sub-data signal DSn−3 may have a voltage level corresponding to a grayscale of an image to be displayed by the third pixel PX3 and may be applied to the (n−3)th sub-data line DLn−3.

As an example of the present disclosure, the active periods of the first control signal CLA and the second control signal CLB do not overlap the second period P2a, and the active period of the third control signal CLC may overlap the second period P2a. That is, the first demux transistor DT1 and the second demux transistor DT2 are turned on at timings different from the second period P2a, and the third demux transistor DT3 may be turned on during the second period P2a. During the second period P2a, the write scan signal GWi is activated, and the data signals DSn−1, DSn−2, and DSn−3 may be applied to the first, second, and third pixels PX1, PX2, and PX3, respectively. As a result, the first and second sub-data signals DSn−1 and DSn−2, which are to be applied to the first and second pixels PX1 and PX2, may not be immediately applied to the first and second pixels PX1 and PX2 when the first and second control signals CLA and CLB are activated, and the first and second sub-data signals DSn−1 and DSn−2 may be held by corresponding (n−1)th and (n−2)th sub-data lines DLn−1 and DLn−2 and may be applied to the first and second pixels PX1 and PX2 when the write scan signal GWi is activated during the second period P2a.

The third sub-data signal DSn−3 applied to the third pixel PX3 may be applied to the third pixel PX3 through the (n−3)th sub-data line DLn−3 when the third control signal CLC is activated and the write scan signal GWi is activated. Since the write scan signal GWi is activated when the third control signal CLC, which is one of the three control signals CLA, CLB, and CLC, is activated during one horizontal scan period 1H, the duration of the second period P2a may be one-third of the horizontal scan period 1H. Accordingly, the duration of the first period P1a may also be set to one-third of the horizontal scan period 1H. According to some embodiments, the duration of the first period P1a be one-third of the duration of the first period P1 illustrated FIG. 6, and the duration of the second period P2a be one-third of the duration of the second period P2 illustrated FIG. 6.

The display device may be applied to various electronic devices. The electronic device may include the display device and may further include a module or device having additional functions in addition to the display device.

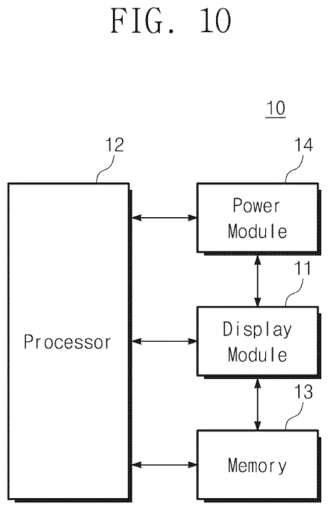

FIG. 10 is a block diagram illustrating the electronic device according to some embodiments of the present disclosure. Referring to FIG. 10, the electronic device 10 may include a display module 11, a processor 12, a memory 13, and a power module 14.

The processor 12 may include at least one of a central processing unit (CPU), an application processor (AP), a graphics processing unit (GPU), a communication processor (CP), an image signal processor (ISP), or a controller. The processor 12 may control the operation of the display device according to some embodiments of the present disclosure.

The memory 13 may store data information required for the operation of the processor 12 or the display module 11. When the processor 12 executes an application stored in the memory 13, an image data signal and/or an input control signal may be transmitted to the display module 11, and the display module 11 may process the received signals to output image information through a display screen.

The power module 14 may include a power supply module, such as a power adapter or a battery device, and a power conversion module that converts power supplied by the power supply module to generate power required for the operation of the electronic device 10.

The electronic device 10 may include the display device according to the embodiments, and at least one of components of the electronic device 10 may be included in the display device according to some embodiments. In addition, among individual modules that are functionally included within a single module, some may be included in the display device while others may be provided separately from the display device. As an example, the display device may include the display module 11, and the processor 12, the memory 13, and the power module 14 may be provided as separate devices within the electronic device 10, rather than being included in the display device.

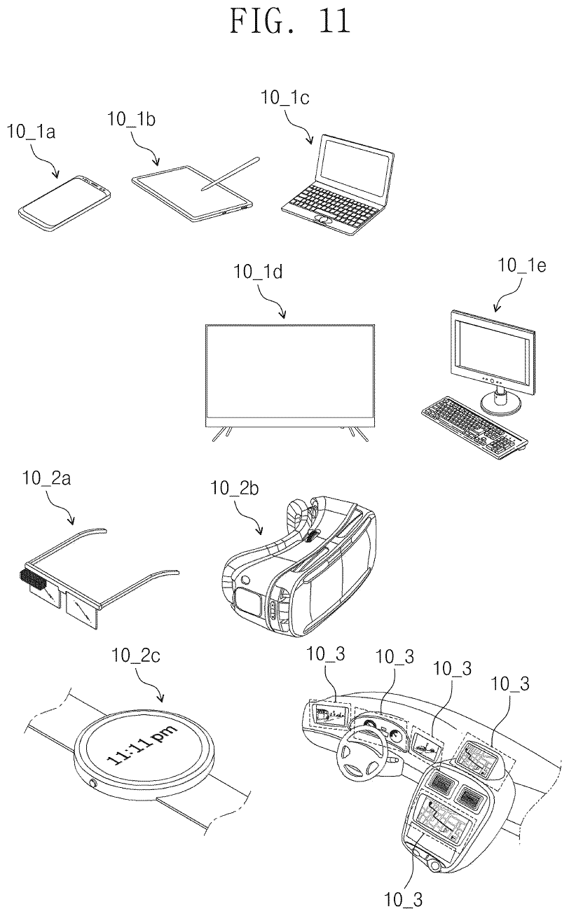

FIG. 11 is a schematic view illustrating electronic devices according to various embodiments of the present disclosure.

Referring to FIG. 11, various electronic devices to which the display device according to some embodiments is applied may include an electronic device for displaying images, such as a smartphone 10_1a, a tablet PC 10_1b, a laptop computer 10_1c, a television 10_1d, a desktop monitor 10_1e, etc., a wearable electronic device including a display module, such as a smart glasses 10_2a, a head-mounted display 10_2b, a smartwatch 10_2c, etc., and an in-vehicle electronic device 10_3 including a display module, such as an instrument panel, a center fascia, a dashboard-mounted center information display (CID), a room mirror display, etc.

Although aspects of some embodiments of the present disclosure have been described, it is understood that embodiments according to the present disclosure should not be limited to these embodiments but various changes and modifications can be made by one ordinary skilled in the art within the spirit and scope of the present disclosure as hereinafter claimed. Therefore, the disclosed subject matter should not be limited to any single embodiment described herein, and the scope of the present inventive concept shall be determined according to the attached claims, and their equivalents.

What is claimed is:

1. A display device comprising:
a semiconductor substrate; and
a plurality of pixels on the semiconductor substrate, each of the pixels comprising:
a light emitting element;
a driving transistor connected between a first driving voltage line configured to receive a first driving voltage and a first node;
a write transistor connected to a data line and configured to receive a write scan signal; and
a switching transistor connected between the first node and the light emitting element and configured to receive a switching scan signal, wherein the switching scan signal comprises a first period having a first voltage level, a second period having a second voltage level, and a third period having a third voltage level.

2. The display device of claim 1, wherein the switching transistor is configured to be turned on in response to the switching scan signal having the first voltage level during the first period and the third voltage level during the third period and is configured to be turned off in response to the switching scan signal having the second voltage level during the second period.

3. The display device of claim 2, wherein the first voltage level is lower than a value obtained by subtracting a threshold voltage of the driving transistor and a threshold voltage of the switching transistor from the first driving voltage.

4. The display device of claim 3, wherein the third voltage level has a voltage level between the first voltage level and the second voltage level.

5. The display device of claim 1, wherein the driving transistor comprises:
a gate connected to a second node;
a source connected to the first driving voltage line; and
a drain connected to the first node.

6. The display device of claim 1, wherein the switching transistor comprises:
a gate configured to receive the switching scan signal;
a source connected to the first node; and
a drain connected to the light emitting element.

7. The display device of claim 1, wherein the write transistor comprises:
a gate configured to receive the write scan signal;
a source connected to the data line; and
a drain connected to a third node.

8. The display device of claim 7, wherein each of the pixels further comprises a compensation transistor, and the compensation transistor comprises:
a gate configured to receive a compensation scan signal;
a source connected to the first node; and
a drain connected to a second node.

9. The display device of claim 8, wherein each of the pixels further comprises an initialization transistor, and the initialization transistor comprises:
a gate configured to receive an initialization scan signal;
a source connected to an initialization voltage line receiving an initialization voltage; and
a drain connected to the light emitting element.

10. The display device of claim 9, wherein each of the pixels further comprises a reference transistor, and the reference transistor comprises:
a gate configured to receive a reference scan signal;
a source connected to a reference voltage line configured to receive a reference voltage; and
a drain connected to the third node.

11. The display device of claim 10, wherein each of the pixels further comprises a capacitor connected between the second node and the third node.

12. The display device of claim 11, wherein the display device is configured to operate in a unit of frame, and the frame comprises the first period, the second period, and the third period.

13. The display device of claim 12, wherein the reference scan signal, the compensation scan signal, and the initialization scan signal comprise an active period in the first period, and the write scan signal comprises a non-active period in the first period.

14. The display device of claim 12, wherein the compensation scan signal, the write scan signal, and the initialization scan signal comprise an active period in the second period, and the reference scan signal comprises a non-active period in the second period.

15. The display device of claim 1, further comprising a demultiplexer, wherein the demultiplexer is configured to transmit a first sub-data signal in response to a first control signal, to transmit a second sub-data signal in response to a second control signal, and to transmit a third sub-data signal in response to a third control signal.

16. The display device of claim 15, wherein the first control signal and the second control signal are configured to be activated at a different time from the second period, and the third control signal is configured to be activated during the second period.

17. The display device of claim 16, wherein the first control signal, the second control signal, and the third control signal are configured to be sequentially activated during a horizontal scan period between the first period and the third period, and a duration of the second period is one-third of the horizontal scan period.

18. An electronic device comprising:
a display device;
a processor configured to control an operation of the display device; and
a power module configured to supply a power, the display device comprising:
a semiconductor substrate; and
a plurality of pixels on the semiconductor substrate, each of the pixels comprising:
a light emitting element;
a driving transistor connected between a first driving voltage line configured to receive a first driving voltage and a first node;
a write transistor connected to a data line and configured to receive a write scan signal; and
a switching transistor connected between the first node and the light emitting element and configured to receive a switching scan signal, wherein the switching scan signal comprises a first period having a first voltage level, a second period having a second voltage level, and a third period having a third voltage level.

19. The electronic device of claim 18, wherein the switching transistor is configured to be turned on in response to the switching scan signal having the first voltage level during the first period and the third voltage level during the third period and is configured to be turned off in response to the switching scan signal having the second voltage level during the second period.

20. The electronic device of claim 18, wherein the first voltage level is lower than a value obtained by subtracting a threshold voltage of the driving transistor and a threshold voltage of the switching transistor from the first driving voltage, and the third voltage level has a voltage level between the first voltage level and the second voltage level.
